(19) United States
(12) Patent Application Publication
(10) Pub. No.: US 2022/0138363 A1
(43) Pub. Date: May 5, 2022

(54) REALIZATION OF DIGITAL TWIN USING XML PARSING OF BUILDING INFORMATION MODELING AND ENERGY VISUALIZATION SYSTEM USING THEREOF

(71) Applicant: Pluxity Co., Ltd., Seoul (KR)

(72) Inventors: Jaemin Yoon, Seoul (KR); Wonwoo Lee, Anyang-si (KR); Insun Baek, Goyang-si (KR); Dongkyu Na, Seoul (KR); Suyeon Cho, Seoul (KR); Seunghyun Yoon, Seoul (KR)

(21) Appl. No.: 17/409,512

(22) Filed: Aug. 23, 2021

(30) Foreign Application Priority Data
Oct. 30, 2020 (KR) 10-2020-0143762

(51) Int. Cl. G06F 30/13; G06F 40/221

(52) U.S. Cl. CPC G06F 30/13; G06F 40/221

(57) ABSTRACT

Disclosed are a system for realizing a digital twin using XML parsing of building information modeling data and an energy visualization system using the same that are implemented by a computing device, which includes: an object information definition module for defining attribute information of an energy consumption-related object constituting indoor spatial information; an address mapping module for defining a grid address for a grid region constituting the one space and mapping an object having attribute information; a digital twin implementation module for implementing digital twin data for the predetermined space in a virtual storage space; and an energy flow visualization module for applying the attribute information of the object and virtual energy application scenario data to the digital twin data, and creating energy flow visualization data.

### BACKGROUND OF THE INVENTION

### 1. Field of the Invention

The present invention relates to a technology that implements a digital twin for a predetermined space and predicts and visualizes an energy flow using the twin, and more particularly, to a technology to create object attribute information based on building information modeling for regions related to energy consumption and production such as buildings and assign an address of an object to the object attribute information based on GS1 code and then visualize the object in a virtual space, thereby efficiently building a digital twin, and visualize an energy flow based on the object attribute information, thereby accurately and efficiently visualizing the energy flow in a specific space.

### 2. Description of the Related Art

A digital twin, as a concept advocated by General Electric company (GE) of the United States, refers to a technology for creating a twin in a computer to correspond to an object in a real world and simulating situations that may occur in the real world using the computer so as to predict results in advance. The digital twin is attracting attention as a technology that can solve various problems in industrial and social fields as well as in a manufacturing field. In addition, the digital twin basically can be referred to as an interface that can understand the past and present operational status and predict the future through a combination of data and information that represent structures, contexts, and actuations of various physical systems. As a powerful digital object that may be used to optimize the physical world, the digital twin recently has been gaining popularity so as to significantly improve operational performance and business processes.

In regard to the digital twin, a digital twin is created in a similar way to a virtual mockup, a program for controlling the digital twin is planted in a tablet of a process manager, and sensors are installed in entire processes of production and consumption, such that signals generated from the sensors are reflected to the digital twin in the tablet in real time. Accordingly, sharers of a digital twin program for a specific product (or process) can check whether a product-related problem has occurred, anytime and anywhere in real time. Almost simultaneously, the optimal solution is derived based on collective intelligence of the sharers and delivered directly to the field, and the most appropriate action is taken. When all products are manufactured and managed in the above manner, the cost losses due to production process errors can be reduced, and consumer needs can be responded more closely.

Basically, the above digital twin is mainly used to predict the occurrence of problems and the like as described above. For example, Korean Unexamined Patent Publication No. 10-2020-0063618 discloses a technology for an architecture that implements a digital twin based on 5 layers about energy consumption to present a technology for implementing layers such as a data-based analysis and optimization, a smart home/building/factory, an electric vehicle, a sensor, infrastructure, etc., and a digital twin-based simulation for the layers, respectively.

However, the above digital twin recites excessively macroscopic energy-related digital twin, that is, recites only the topics to which the digital twin related to energy is implemented, as a result, only the technology limited to the above-described problem prediction may be implemented.

However, when the digital twin is implemented for energy flows in specific buildings and regions, it is necessary to accurately predict energy consumption and production by visualizing the flow of energy and consider energy factors of various objects constituting the corresponding space, and the digital twin also requires an implementation scheme optimized thereto and a technology for visualizing the energy flows using the scheme.

### SUMMARY OF THE INVENTION

Accordingly, the present invention provides a technology for realizing a digital twin capable of accurately and intuitively visualizing an energy flow.

In addition, the present invention still provides an energy digital twin technology, upon implementation of a digital twin, for implementing an energy digital twin technology applicable to a new and renewable energy complex, a general building energy system, and the like, and enabling development in the form of a web service based on HTML5 web standard, by using complex addresses for multi-story buildings and spaces.

In order to achieve the above objectives, one embodiment of the present invention relates to a system for realizing a digital twin using XML parsing of building information modeling data and an energy visualization system using the same, which are implemented by a computing device including one or more processors and one or more memories for storing instructions executable in the processors. The system includes: an object information definition module for defining attribute information of an energy consumption-related object constituting indoor spatial information through XML parsing from building information modeling (BIM) data constituting a predetermined space; an address mapping module for defining a grid address for a grid region constituting the one space based on geographic information system (GIS)-based data for the predetermined space, and mapping an object having attribute information defined by the object information definition module to the defined grid address; a digital twin implementation module for implementing digital twin data for the predetermined space in a virtual storage space, based on shape information of the object previously stored in a database and the grid address of each object; and an energy flow visualization module for applying the attribute information of the object and virtual energy application scenario data to the digital twin data, and creating energy flow visualization data in which the shape information of the object, the attribute information of the object, and an energy flow for the predetermined space are visualized.

It may be preferable that the object information definition module defines an object, which matches object information defined in an architectural object information exchange standard format (Industry Foundation Classes (IFC)) among objects constituting an indoor space included in the building information modeling data, as an object serving as a target of definition of the attribute information, and defines data, which corresponds to each defined object among the XML data parsed using an IFC-to-GML conversion module, as the attribute information of the object.

It may be preferable that the object is one of objects definable as CityGML-based extended attribute among the indoor spatial information, as an object configured to be classified into layers based on a shape and an object for consuming or producing energy among facilities constituting the indoors.

It may be preferable that the attribute information of the object includes information about size, position, height, orientation, and energy consumption-related specifications of each object.

It may be preferable that the address mapping module transforms a region constituting the predetermined space into coordinates based on the standard coordinate system by using a preset standard coordinate system including at least a country point number EPSG:5179 coordinate system and coordinate data on the geographic information system of the predetermined space, and maps the grid address information of each object including coordinate information and code information for each object based on the converted coordinates and GS1 code-based code information assigned through a preset code assignment rule for each object.

It may be preferable that the energy flow visualization module visualizes the energy flow based on at least information included in the attribute information of the object, such as information about a type of energy related to each object, information about an amount of energy consumption of the object, and information about an energy flow direction with respect to the object.

It may be preferable that, when receiving an energy type selection input of a user account for a user interface for outputting the energy flow visualization data, the energy flow visualization module displays an object related to an energy type corresponding to the selection input in a preset chromatic color, and visualizes other objects by using shadows.

It may be preferable that the energy flow visualization module displays the energy flow in a different color depending on the type of energy.

According to the present invention, XML parsing is performed using a standard scheme of transforming the building information model (BIM) into CityGML as a type of XML to identify elements constituting the space as objects based on an object that may be defined as an extended attribute based on CityGML or an object that may be divided into layers based on shapes among the indoor spatial information on objects included in the building information model, and attribute information of the object extracted through the XML parsing is defined, so that the objects and the attribute information are implemented as a digital twin in the virtual space.

Because at least specifications for consumption and production of energy are defined in the attribute information of the object, the digital twin for the energy flow can be implemented in a very simple and intuitive manner, and the energy flow can be visualized when a corresponding scenario is applied.

Accordingly, the digital twin in the form of a web service based on the HTML5 web standard as an XML parsing base can be implemented and the visualization service of the energy flow using the digital twin can be provided. In addition, the digital twin according to the above-described detailed object attribute definition is implemented, so that the digital twin can be applied to a new renewable energy complex, a general building energy system, and the like.

### BRIEF DESCRIPTION OF THE DRAWINGS

FIG. 1 is a diagram for explaining a visualization process of an energy flow using a digital twin according to one embodiment of the present invention.

FIG. 2 is a schematic diagram showing a system for realizing a digital twin using XML parsing of building information modeling data and an energy visualization system using the same according to one embodiment of the present invention.

FIG. 3 is a diagram for explaining an example in which object attribute information is defined according to one embodiment of the present invention.

FIG. 4 is an example of visualizing a flow of CityGML data exported from BIM data by using IFC items according to one embodiment of the present invention.

FIG. 5 is a diagram for explaining a flow of mapping grid address information of an object according to one embodiment of the present invention.

FIGS. 6 and 7 are examples in which the energy flow is visualized in a user terminal according to one embodiment of the present invention.

FIG. 8 shows one example of an internal configuration of a computing device according to one embodiment of the present invention.

### DETAILED DESCRIPTION OF THE INVENTION

Hereinafter, various embodiments and/or aspects will be described with reference to the drawings. In the following description, numerous specific details are set forth in order to provide a thorough understanding of one or more aspects for the purpose of explanation. However, it will also be appreciated by a person having ordinary skill in the art that such aspect(s) may be carried out without the specific details. The following description and accompanying drawings will be set forth in detail for specific illustrative aspects among one or more aspects. However, the aspects are merely illustrative, some of various ways among principles of the various aspects may be employed, and the descriptions set forth herein are intended to include all the various aspects and equivalents thereof.

The terms “embodiment”, “example”, “aspect” or the like used in the present specification may not be construed in that an aspect or design set forth herein may be preferable or advantageous than other aspects or designs.

In addition, the terms “include” and/or “comprise” specify the presence of the corresponding feature and/or element, but do not preclude the possibility of the presence or addition of one or more other features, elements or combinations thereof.

In addition, the terms including an ordinal number such as first and second may be used to describe various elements, however, the elements are not limited by the terms. The terms are used only for the purpose of distinguishing one element from another element. For example, the first element may be referred to as the second element without departing from the scope of the present invention, and similarly, the second element may also be referred to as the first element. The term “and/or” includes any one of a plurality of related listed items or a combination thereof.

In addition, unless defined otherwise in embodiments of the present invention, all terms used herein including technical or scientific terms have the same meaning as commonly understood by those having ordinary skill in the art. Terms such as those defined in generally used dictionaries will be interpreted to have the meaning consistent with the meaning in the context of the related art, unless expressly defined in the embodiments of the present invention, will not be construed as an ideal or excessively formal meaning.

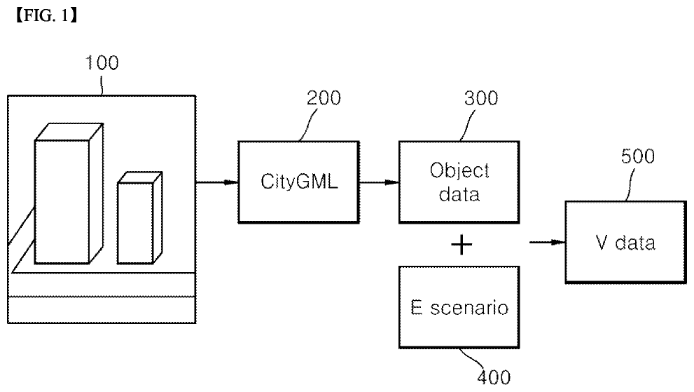

FIG. 1 is a diagram for explaining a visualization process of an energy flow using a digital twin according to one embodiment of the present invention.

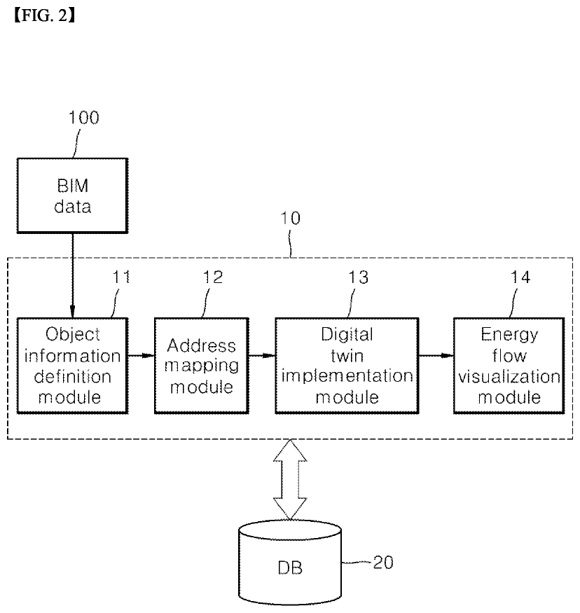

FIG. 2 is a schematic diagram showing a system for realizing a digital twin using XML parsing of building information modeling data and an energy visualization system using the same according to one embodiment of the present invention.

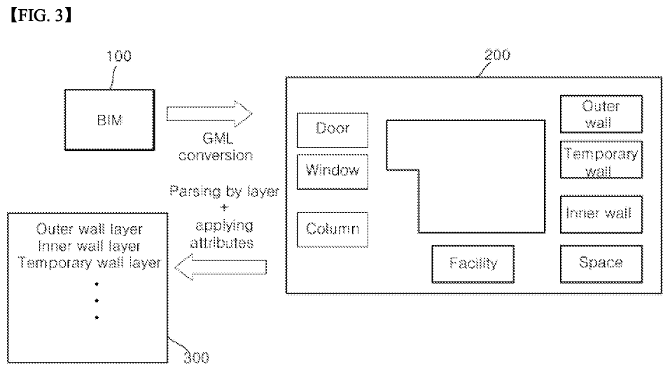

FIG. 3 is a diagram for explaining an example in which object attribute information is defined according to one embodiment of the present invention.

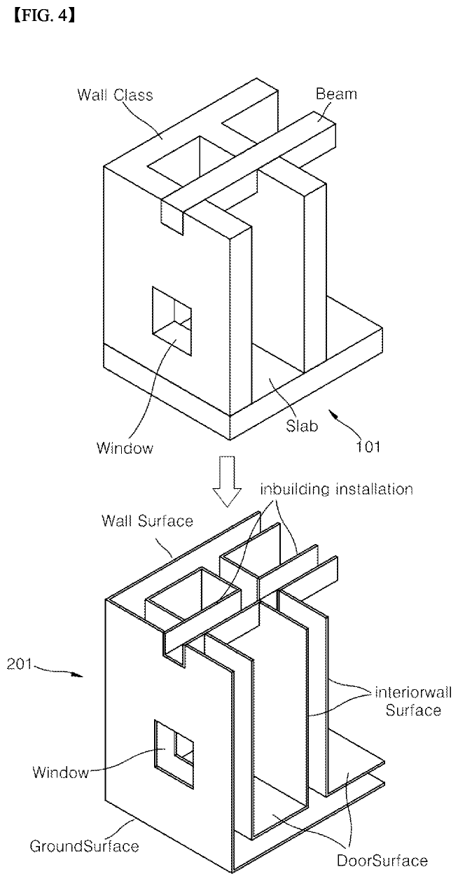

FIG. 4 is an example of visualizing a flow of CityGML data exported from BIM data by using IFC items according to one embodiment of the present invention.

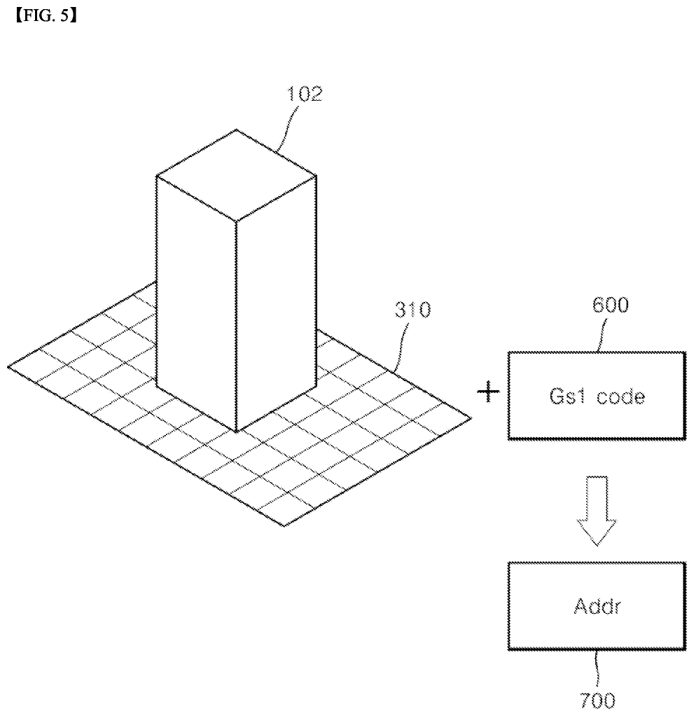

FIG. 5 is a diagram for explaining a flow of mapping grid address information of an object according to one embodiment of the present invention.

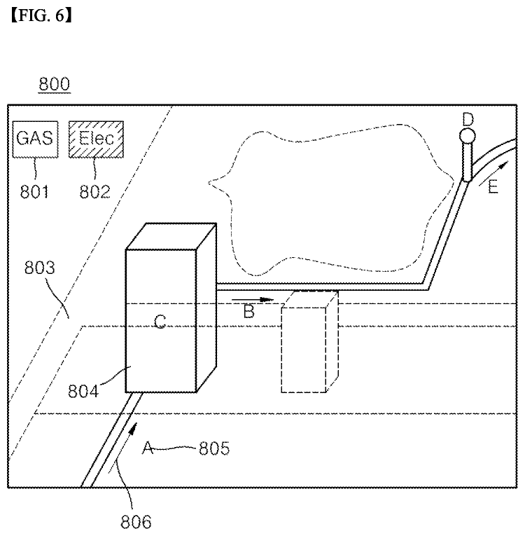

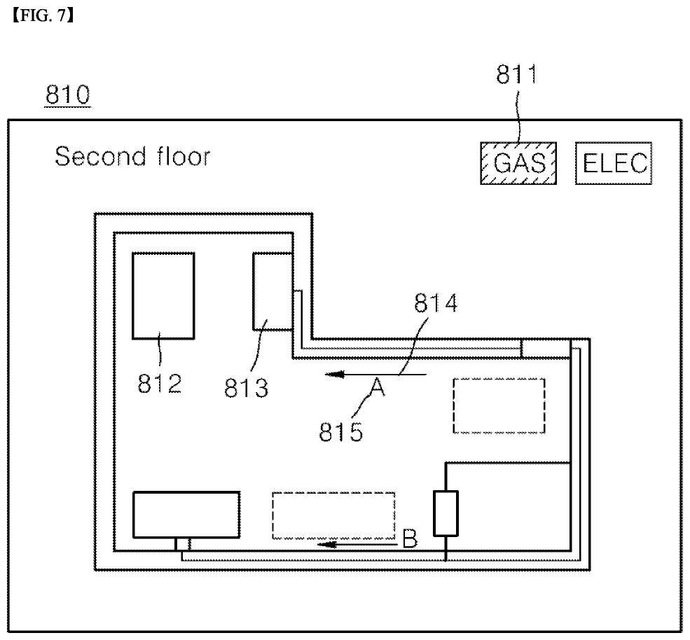

FIGS. 6 and 7 are examples in which the energy flow is visualized in a user terminal according to one embodiment of the present invention.

When described with reference to the above drawings, the system for realizing a digital twin using XML parsing of building information modeling data and the energy visualization system using the same according to one embodiment of the present invention 10 (hereinafter, referred to as a system of the present invention or a system) include an object information definition module 11, an address mapping module 12, a digital twin implementation module 13, and an energy flow visualization module 14 as shown in FIG. 2, and all data, algorithms, programs, interface data, and the like processed in the system 100 or stored and managed to perform a function of the system may be stored and managed in a database 20.

As shown in FIGS. 1 and 2, the system 10 of the present invention uses building information modeling data as a result of performing energy facility modeling based on the building information model (BIM) upon constructing a three-dimensional space to model one space to be implemented so as to implement a digital twin for visualize the energy flow.

BIM is a technology for creating information and models necessary for design, construction and operation throughout the life cycle of facilities in the entire construction field by using a 3D virtual space evolved by further step from the existing floor plan design using CAD or the like. The BIM, basically, is understood as the concept of adding attribute information about a model to the 3D CAD.

When the BIM is used, the attribute information about the model is capable of the quotation using prices for a building, the error detection through double checks due to existence of separate drawings for each construction type, the environment analysis, the maintenance and repair, the simulation during construction, the calculation of area and volume. According to the present invention, XML parsing is performed by converting building information model 100 including various information as described as in FIG. 1 into CityGML data 200 which is one of XML, attribute information 300 of each object constituting the space is defined using the CityGML data, a digital twin is constructed based on the defined attribute information, and a scenario 400 for an energy flow is applied to the digital twin, thereby performing a function of generating and providing visualization data 500 that visualizes the energy flow in the digital twin for a predetermined virtual space.

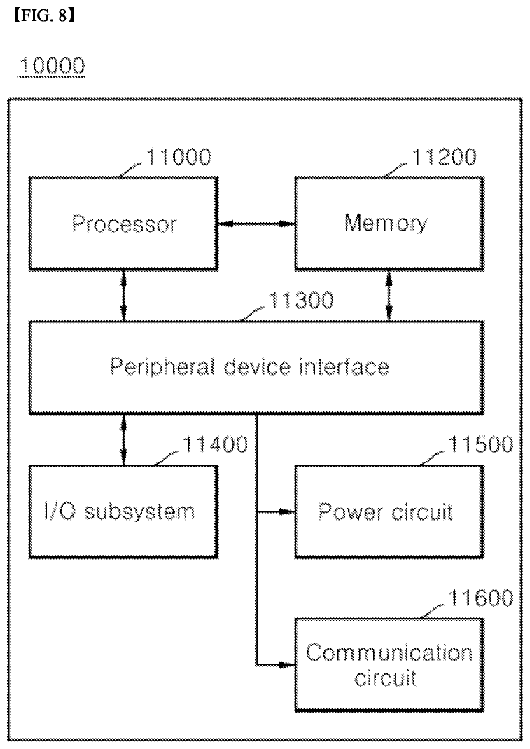

The system 10 is a concept including performance of the above-described functions and the above-described configuration, and may be implemented by a computing device including one or more processors and one or more memories for storing instructions executable in the processors, as shown in FIG. 8 for example.

First, the object information definition module 11 performs a function of defining attribute information of an object related to energy consumption constituting indoor spatial information through XML parsing from building information modeling (BIM) data constituting on a predetermined space.

The indoor spatial information refers to information about each space constituting a predetermined building, and signifies information identified as objects constituting the space. In the present invention, the object refers to a unit, such as an indoor object or an object distinguishing indoor and outdoor spaces, that is related to energy consumption and production within the predetermined building or space, or that may define the indoor space. For example, doors, exterior walls, interior walls, temporary walls, windows, and facilities for energy consumption and production (such as air conditioning equipment, lighting equipment) may be included in the object according to the present invention.

At this point, the object information definition module defines the attribute information of the object through the XML parsing from the above-mentioned BIM data, that is, building information modeling data. Specifically, it may be preferable that, for example, the object information definition module 11 according to the present invention defines an object, which matches object information defined in an architectural object information exchange standard format (Industry Foundation Classes (IFC)), as an object serving as a target of definition of the attribute information among the objects constituting the indoor space included in the building information modeling data, and defines data, which corresponds to each defined object among the XML data parsed using an IFC-to-GML conversion module, as the attribute information of the object.

The XML parsing refers to a determination of a structure by decomposing elements constituting data of a specific format into an XML format and analyzing hierarchical relationships between the decomposed elements. In other words, the XML parsing refers to a process of disassembling and analyzing data, assembling the data into a desired form, and extracting the fata again. Thus, information provided on the web is processed into the form the user wants and called back from a server.

The above XML parsing in the present invention is used for the CityGML conversion from necessary information among building information modeling data. In particular, as mentioned above, objects matching the object information defined in the above-described IFC among the objects constituting the indoor space included in the BIM data are defined as objects to be defined in the present invention. Thereafter, each information is redefined through the XML parsing by using an IFC-to-GML conversion module, and then data corresponding to the defined object is extracted using the structural relationships of the information, mapped for each object, and defined as the attribute information of the object.

The physical expression of the IFC is expressed in an STEP format, which has been used for a long time in the machine field, or an XML format, which is widely used in the Web. The above format has been developed by buildingSMART (International Alliance for Interoperability; IAI), created to support interoperability between fields of architecture, engineering and construction (AEC), and registered by ISO/PAS 16739 as standard.

The IFC defines data about objects through the relationship between objects. All that constitute a building includes (aggregates) objects and there is an association between the objects. The superordinate concept of the object is Root, and the Root may have a unique ID of the object. The object has an attribute used as attribute information of the object in the present invention. In addition, Product conceptually derived from the object has Geometries (geometric shapes). In addition, Materials are included. Element derived from Product may be further divided into BuildingElement (building element), StructuralElement (structural element), and MepElement (MEP element). The building elements are further particularly divided into elements such as walls, floors, ceilings, and roofs.

In regard to elements constituting the object, the elements of the object are identified and analyzed through an object attribute representing an intrinsic attribute and material of the object, an object behavior expressing a behavior of the object, and an object relationship representing a relationship between the objects.

When the module for converting IFC into CityGML is used, the elements constituting the object may be parsed among the above-described BIM data, and the object and the attribute information may be defined therefrom.

The BIM data is parsed in the XML format. This is because data in the extensible markup language (XML) format is required to implement the digital twin for visualizing energy flow based on HTML5 web standard when the digital twin is implemented using professional data such as BIM.

After the parsing, the attribute information of the object is implemented upon completion of the transformation process of constructing an integrated CityGML schema by establishing the parsed XML data. The parsed XML data has the CityGML format as described above, and is converted to CityGML3.0-based data, for example.

The concept of CityGML3.0 is defined as a multi-representation framework, a semantic representation for an indoor floor, a room definitions, and a building site management, a development of new facility model for application considering texture and material properties, dynamic objects, a utility network representation suitable for analysis and simulation, an alternate representation considering IFC solid objects, a file version, a plan, a multi-history information management, a parametric form, or linked open data (LOD) that classifies internal and external objects and considers semantics.

At this point, the object is designated as an object to be converted from confirmation matched with object information defined in IFC among BIM data as described above. To this end, referring to FIG. 3, when BIM data 100 is converted to CityGML 200, the object matched with the object information defined in the IFC is defined as an object among objects constituting an indoor space of a target building.

At this point, criteria for matching, that is, the object may be defined as follows. For example, an object capable of defining a facility serving as an object that may be identified as a layer based on a shape, such as a door, a window, a column, an interior wall, an exterior wall, a temporary wall, a floor, and a ceiling, or an object that may be defined as a CityGML extended attribute among indoor spatial information may be defined as the object in the present invention. After the above-described parsing is performed on the objects for each layer, data parsed from the BIM data is applied to each object to reflect the attribute, so that the attribute information 300 of the object is defined.

An example of the conversion is shown in FIG. 4. It can be seen that a wall class, a beam, a window, a slab and the like may be defined as shown in the IFC 101, as objects definable in an IFC 101 of FIG. 4.

When the IFC is converted to CityGML 201, the objects may be defined using the above-described association and the like. Referring to the above example, the building of the CityGML includes a surface (BoundarySurface) such as wall, ceiling or floor, a space (Room) such as room and hallway, an open space (Opening), such as door or window, that exists between spaces, indoor and outdoor facilities of the building (InBuilding Installation, BuildingInstallation), and furniture (BuildingFurniture) that exists indoors. For example, Room may represent the geometry in two forms through features of LOD4. The Room may be may be represented as GML's geometric object solid (gml:Solid) or aggregated surface (gml:MultiSurface), or as a set of topologically enclosing BoundarySurfaces.

Meanwhile, structures such as ceilings, roofs, and floors constituting the building are expressed as BoundarySurface, which is not a three-dimensional object but a surface, in CityGML 201. In other words, the structure is defined to emphasize surfaces viewed from a viewpoint of a three dimensional visualization rather than a unit of component. Outer peripheral surfaces of the building expressed in LOD3 include RoofSurface, WallSurface, OuterCeilingSurface, OuterFloorSurface, and GroundSurface, and indoor surfaces expressed in LOD4 include InteriorWallSurface, CeilingSurface, and FloorSurface.

Since only the Room class exists as the indoor space in CityGML 201, it is necessary to clearly distinguish whether the space is GeneralSpace or TransitionSpace of IndoorGML. The indoor space created with CityGML may be semantically classified and corresponded to a class of IndoorGML.

The objects may be defined as described above, and may be defined as an object associated with consuming or producing energy to perform the functions according to the present invention. Accordingly, it may be preferable that the attribute information of the object is information about the size, position, height, orientation, and energy consumption-related specifications of each object. The energy consumption-related specifications may include the presence of consumption or production of energy, the amount of consumption (production) per unit time of the energy, the amount of consumption (production) of the energy for each driving state.

Meanwhile, the address mapping module 12 performs a function of defining a grid address for a grid region constituting the one space based on geographic information system (GIS)-based data for the predetermined space, and mapping an object having attribute information defined by the object information definition module 11 to the defined grid address.

The data based on geographic information system (GIS) is defined as the grid addresses. For example, the GIS-based data is defined for an actual space corresponding to each BIM data. The data is required to be reflected in the virtual digital twin so that each object is accurately implemented in the virtual space. To this end, the address mapping module 12 defines the GIS as the grid address in order to implement the GIS-based data in the virtual space corresponding to a predetermined space as described above.

In order to define the grid addresses according to the present invention, the address mapping module 12, as specifically shown in FIG. 5, transforms a region constituting the predetermined space into coordinates based on the standard coordinate system 310 by using, for example, a preset standard coordinate system including a country point number EPSG:5179 coordinate system and coordinate data on the geographic information system of the on a predetermined space, and maps the grid address information 700 of each object including coordinate information and code information for each object, based on the converted coordinates and GS1 code-based code information 600 assigned through a preset code assignment rule for each object included in the building 102.

In other words, the address on a plane is defined based on the standard coordinate system first, code information 600 is assigned to objects that may exist in a plurality on the corresponding address through the GS1 code assignment, and then the grid address information 700 of each object is mapped/defined by using the coordinates according to the standard coordinate system and the code information 600.

The GS1 code, as an identification code for various uses for managing products, services, locations, assets and the like, is the world's only international standard code. Code that can define an object through the GS1 code may specify the object by combining various numbers based on GS1 code for business operators.

When the grid address information 700 of objects is mapped, defined and implemented in the digital twin by using the above-described coordinates and code information 600, the grid address 700 and the GS1 code 600 are mapped to create a domain through a domain conversion algorithm, and various data management service functions may be provided through a DNS request for the domain.

In particular, a service such as EPCIS may be provided by using the GS1 code. Events and the like for the GS1 code are recorded, so that data about the object that varies in real time may be captured and stored in the server or the like, and required data according to the above data and other services may be provided in an XML or JSON format. For example, information about the manufacturing time and the management history of each object may be provided.

On the other hand, the objects may include a plurality of unit grids in the above-described standard coordinate system, in which the address may be assigned while calculating a grid rectangle included in the object through the known Flood Fill algorithm and filling a rectangle therein.

When the object, the attribute information of the object, and the grid address of the objects are defined in the above manner, the digital twin implementation module 13 performs the function of implementing digital twin data for a predetermined space in the virtual storage space, based on the shape information of the object previously stored in the database 20 and the grid address of each object. In other words, the shape information of the object may be managed in the database 20 in a manner of a standard library or the like. At this point, when the object's identification information, attribute information, and grid address are used, a real space may be implemented as it is in the virtual digital space. In particular, the digital twin capable of implementing the energy flow may be implemented by using the attribute information of the object.

When the above digital twin is implemented, the energy flow visualization module 14, for visualization of the energy flow, performs a function of applying the attribute information of the object and the virtual energy application scenario data to digital twin data, and generating the energy flow visualization data in which the shape information of the object, the attribute information of the object, and the energy flow for the predetermined space are visualized. The energy flow visualization data generated in the above manner is provided to the user terminal and the like, so that the energy flow in the predetermined space may be predicted through the digital twin.

Examples thereof are shown in FIGS. 6 and 7. Referring to the drawings together, it may be preferable that the energy flow visualization module 14 visualizes the energy flow based on at least information included in the attribute information of the object, such as information about a type of energy related to each object, information about an amount of energy consumption of the object, and information about an energy flow direction with respect to the object, so as to visualize the energy flow in the predetermined space implemented as the digital twin.

As shown in screens 800 and 810 of FIGS. 6 and 7, information on the type of energy related to each object refers to information capable of identifying the type of energy to be consumed or produced, such as gas 801 and 811 or electricity 802. Information on energy consumption refers to information defined as the above-described attribute information of the object. Energy flow direction information refers to information through the association between objects, for example, information about a direction to which the energy flows between the objects when electricity is used in a load while flows through a line.

As shown in FIG. 6 the energy flow visualization data between spaces, which are sets of objects in a predetermined space, may be defined from a macro viewpoint, and may be defined by combining the attribute information of each object. In addition, as shown in FIG. 7, the energy flow visualization data may be defined in association with the attribute information of each object from a viewpoint of a predetermined building unit.

As shown in FIGS. 6 and 7, the directions 806 and 814 of each energy flow may be visualized, and energy consumption (production) amounts 805 and 815 may be visualized. Meanwhile, as electricity 802 in FIG. 6 and gas 811 in FIG. 7, when the energy type selection input of the user account is received for the user interface screens 800 and 810 on which the energy flow visualization data is outputted, objects (solid lines such as 804 and 813) related to the energy type corresponding to the selection input may be displayed in a preset chromatic color, and other objects (dashed lines such as 803 and 812) may be visualized by using shadows. Accordingly, users may intuitively check each energy flow visualization data for each energy. Similarly, although not shown in FIGS. 6 and 7, the energy flow visualization module 14 may display the energy flow in different colors depending on the type of energy.

Accordingly, the digital twin for the energy flow can be implemented in a very simple and intuitive manner, and the energy flow can be visualized when a corresponding scenario is applied.

In addition, the digital twin in the form of a web service based on the HTML5 web standard as an XML parsing base can be implemented and the visualization service of the energy flow using the digital twin can be provided. In addition, the digital twin according to the above-described detailed object attribute definition is implemented, so that the digital twin can be applied to a new renewable energy complex, a general building energy system, and the like.

FIG. 8 shows one example of an internal configuration of a computing device according to one embodiment of the present invention. In the following description, unnecessary descriptions for embodiments redundant with those of FIGS. 1 to 4 will be omitted.

As shown in FIG. 8, the computing device 10000 may at least include at least one processor 11100, a memory 11200, a peripheral device interface 11300, an input/output subsystem (I/O subsystem) 11400, a power circuit 11500, and a communication circuit 11600. The computing device 10000 may correspond to a user terminal A connected to a tactile interface device or correspond to the above-mentioned computing device B.

The memory 11200, may include, for example, a high-speed random access memory, a magnetic disk, an SRAM, a DRAM, a ROM, a flash memory, or a non-volatile memory. The memory 11200 may include a software module, an instruction set, or other various data necessary for the operation of the computing device 10000.

The access to the memory 11200 from other components of the processor 11100 or the peripheral interface 11300, may be controlled by the processor 11100.

The peripheral interface 11300 may combine an input and/or output peripheral device of the computing device 10000 to the processor 11100 and the memory 11200. The processor 11100 may execute the software module or the instruction set stored in memory 11200, thereby performing various functions for the computing device 10000 and processing data.

The input/output subsystem 11400 may combine various input/output peripheral devices to the peripheral interface 11300. For example, the input/output subsystem 11400 may include a controller for combining the peripheral device such as monitor, keyboard, mouse, printer, or a touch screen or sensor, if needed, to the peripheral interface 11300. According to another aspect, the input/output peripheral devices may be combined to the peripheral interface 11300 without passing through the I/O subsystem 11400.

The power circuit 11500 may provide power to all or a portion of the components of the terminal. For example, the power circuit 11500 may include a power failure detection circuit, a power converter or inverter, a power status indicator, a power failure detection circuit, a power converter or inverter, a power status indicator, or any other components for generating, managing, and distributing the power.

The communication circuit 11600 may use at least one external port, thereby enabling communication with other computing devices.

Alternatively, as described above, the communication circuit 11600 may include an RF circuit as needed to transmit and receive an RF signal, also known as an electromagnetic signal, thereby enabling communication with other computing devices.

The above embodiment of FIG. 8 is merely an example of the computing device 10000, and the computing device 11000 may have a configuration or arrangement in which some components shown in FIG. 8 are omitted, additional components not shown in FIG. 8 are further provided, or at least two components are combined. For example, a computing device for a communication terminal in a mobile environment may further include a touch screen, a sensor or the like in addition to the components shown in FIG. 8, and the communication circuit 1160 may include a circuit for RF communication of various communication schemes (such as Wi-Fi, 3G, LTE, Bluetooth, NFC, and Zigbee). The components that may be included in the computing device 10000 may be implemented by hardware, software, or a combination of both hardware and software which include at least one integrated circuit specialized in a signal processing or an application.

The methods according to the embodiments of the present invention may be implemented in the form of program instructions to be executed through various computing devices so as to be recorded in a computer-readable medium. In particular, a program according to the embodiment of the present invention may be configured as a PC-based program or an application dedicated to a mobile terminal. The application to which the present invention is applied may be installed in a user terminal through a file provided by a file distribution system. For example, a file distribution system may include a file transmission unit (not shown) that transmits the file according to the request of the user terminal.

The above-mentioned device may be implemented by hardware components, software components, and/or a combination of the hardware components and the software components. For example, the devices and components described in the embodiments may be implemented by using at least one general purpose computer or special purpose computer, for example, a processor, a controller, an arithmetic logic unit (ALU), a digital signal processor, a microcomputer, a field programmable gate array (FPGA), a programmable logic unit (PLU), a microprocessor, or any other device capable of executing and responding to instructions. The processing device may execute an operating system (OS) and at least one software application executed on the operating system. In addition, the processing device may access, store, manipulate, process, and create data in response to the execution of the software. For the further understanding, some cases may have described that one processing device is used, however, it will be appreciated by those skilled in the art that the processing device may include a plurality of processing elements and/or a plurality of types of processing elements. For example, the processing device may include a plurality of processors or one processor and one controller. In addition, other processing configurations, such as a parallel processor, are also applicable.

The software may include computer program, code, instruction, or at least one combination thereof, may configure the processing device to operate as desired, or may instruct the processing device independently or collectively. The software and/or data may be permanently or temporarily embodied in any type of machine, component, physical device, virtual equipment, and computer storage medium or device, in order to be interpreted by the processor or to provide instructions or data to the processor. The software may be distributed over computing devices connected to networks, so as to be stored or executed in a distributed manner. The software and data may be stored in at least one computer-readable recording media.

The method according to the embodiment may be implemented in the form of program instructions to be executed through various computing mechanisms, so as to be recorded in a computer-readable medium. The computer-readable medium may include program instructions, data files, data structures, and the like, independently or in combination thereof. The program instructions recorded on the media may be specially designed and configured for the embodiment, or may be known to those skilled in the art of computer software so as to be used. An example of the computer-readable medium includes a magnetic media such as a hard disk, a floppy disk and a magnetic tape, an optical media such as a CD-ROM and a DVD, a magneto-optical media such as a floptical disk, and a hardware device specially configured to store and execute a program instruction such as ROM, RAM, and flash memory. An example of the program instruction includes a high-level language code to be executed by a computer using an interpreter or the like as well as a machine code generated by a compiler. The above hardware device may be configured to operate as at least one software module to perform the operations of the embodiments, and vise versa.

Although the above embodiments have been described with reference to the limited embodiments and drawings, however, it will be understood by those skilled in the art that various changes and modifications may be made from the above-mentioned description For example, even though the described descriptions may be performed in an order different from the described manner, and/or the described components such as system, structure, device, and circuit may be coupled or combined in a form different from the described manner, or replaced or substituted by other components or equivalents, appropriate results may be achieved. Therefore, other implementations, other embodiments, and equivalents to the claims are also within the scope of the following claims.

What is claimed is:

1. A system for realizing a digital twin using XML parsing of building information modeling data and for visualizing energy system using the digital twin, which is implemented by a computing device including one or more processors and one or more memories for storing instructions executable in the processors, the system comprising:
an object information definition module for defining attribute information of an energy consumption-related object constituting indoor spatial information, through XML parsing from building information modeling (BIM) data constituting a predetermined space;
an address mapping module for defining a grid address for a grid region constituting the one space based on geographic information system (GIS)-based data for the predetermined space, and mapping an object having attribute information defined by the object information definition module to the defined grid address;
a digital twin implementation module for implementing digital twin data for the predetermined space in a virtual storage space, based on shape information of the object previously stored in a database and the grid address of each object; and
an energy flow visualization module for applying the attribute information of the object and virtual energy application scenario data to the digital twin data, and creating energy flow visualization data in which the shape information of the object, the attribute information of the object, and an energy flow for the predetermined space are visualized.

2. The system of claim 1, wherein the object information definition module defines an object, which matches object information defined in an architectural object information exchange standard format (Industry Foundation Classes (IFC)) among objects constituting an indoor space included in the building information modeling data, as an object serving as a target of definition of the attribute information, and defines data, which corresponds to each defined object among the XML data parsed using an IFC-to-GML conversion module, as the attribute information of the object.

3. The system of claim 2, wherein the object is one of objects definable as CityGML-based extended attribute among the indoor spatial information, as an object configured to be classified into layers based on a shape and an object for consuming or producing energy among facilities constituting the indoors.

4. The system of claim 3, wherein the attribute information of the object includes information about size, position, height, orientation, and energy consumption-related specifications of each object.

5. The system of claim 1, wherein the address mapping module transforms a region constituting the predetermined space into coordinates based on the standard coordinate system by using a preset standard coordinate system including at least a country point number EPSG:5179 coordinate system and coordinate data on the geographic information system of the predetermined space, and maps the grid address information of each object including coordinate information and code information for each object, based on the converted coordinates and GS1 code-based code information assigned through a preset code assignment rule for each object.

6. The system of claim 1, wherein the energy flow visualization module visualizes the energy flow based on at least information included in the attribute information of the object, such as information about a type of energy related to each object, information about an amount of energy consumption of the object, and information about an energy flow direction with respect to the object.

7. The system of claim 6, wherein, when receiving an energy type selection input of a user account for a user interface for outputting the energy flow visualization data, the energy flow visualization module displays an object related to an energy type corresponding to the selection input in a preset chromatic color, and visualizes other objects by using shadows.

8. The system of claim 6, wherein the energy flow visualization module displays the energy flow in a different color depending on the type of energy.
